(19) United States
(12) Patent Application Publication
(10) Pub. No.: US 2012/0319741 A1
(43) Pub. Date: Dec. 20, 2012

(54) REDUCED CROSSTALK WIRING DELAY EFFECTS THROUGH THE USE OF A CHECKERBOARD PATTERN OF INVERTING AND NONINVERTING REPEATERS

(75) Inventor: Patrick Bosshart, Plano, TX (US)

(73) Assignee: TEXAS INSTRUMENTS INCORPORATED, Dallas, TX (US)

(21) Appl. No.: 13/163,503

(22) Filed: Jun. 17, 2011

(51) Int. Cl. H03K 3/00; H01L 21/50

(52) U.S. Cl. 327/109; 29/25.01

(57) ABSTRACT

A buffer arrangement in wire lines in which at least one aggressor wire line is located adjacent and substantially parallel to a victim wire line has a plurality of alternately arranged inverting and noninverting buffers. The alternately arranged in a checkerboard pattern in which noninverting and inverting buffers are located in the victim wire line in locations corresponding to locations of the inverting and noninverting buffers in the at least one aggressor wire line.

### FIELD

The various circuit embodiments described herein relate in general to buffer arrangement in wiring lines in semiconductor products, and, more specifically, to methods and structures for buffer arrangements in wire lines in semiconductor products to reduce the effects of crosstalk between adjacent wire lines.

### BACKGROUND

When significant numbers of long wires, or wire lines, need to be run on a VLSI chip, repeaters are used to rebuffer the signal at intervals short enough to keep the RC delay of a single wire line segment down to an acceptable amount. However, a significant portion of the capacitance of a wire line is to its adjacent neighbors. It is a well-known effect that when those wire lines are switching in an opposite direction to the wire line of interest, the effective capacitance of the wire line is increased, along with a resulting delay. This is illustrated in FIG. 1 to which reference is now made.

In FIG. 1, a portion of a wiring run 10 is shown, illustrating two wire lines from a signal source 12 to signal destinations 14 and 16. With respect to the signals in the wire lines, the neighbor wire lines are referred to as an aggressor wire line 18 and a victim wire line 20 for convenience. Thus, for example, when considering the effects of signals in the lower wire line, in the example, on signals in the upper wire line, the lower wire line is referred to as the aggressor wire line 18 and the upper wire is referred to as the victim wire line 20.

At various locations along the aggressor wire line 18 and victim wire line 20, signal repeaters, referred to herein as buffers, are provided, an inverting buffer 22 being shown in the victim wire line 20 for illustration. The inverting buffer 22 separates the victim wire line 20 into two segments 24 and 26. Segment 26 is coupled by a parasitic capacitance 28 to the aggressor wire line 18. Although the parasitic capacitance 28 is shown for illustration as a single capacitor, it will be understood that the capacitance is distributed along the entire length of the segment 26 and a corresponding length of the aggressor wire line 18.

As a result of the parasitic capacitance 28, the victim wire line 20 suffers a delay degradation when signals of opposite direction are simultaneously applied to the victim wire line 20 and aggressor wire line 18. Thus, for example, if a signal having a rising edge 30 at the output of the buffer 22 reaches the segment 26 at the same time as a signal 32 having a falling edge reaches the capacitively coupled portion of the aggressor wire line 18, a portion of the transition of the signal 30 is canceled. This results in crosstalk-induced delay of the signal 30. Although efforts have been made to reduce the crosstalk and its effects, there is limited freedom to reduce the crosstalk-induced delay deltas, for instance, by spacing the wire lines farther apart, because that reduces wiring density, the number of wire lines that can carry signals in a given area.

One technique for reducing crosstalk that has been employed is using inverting buffers that are staggered between adjacent wire lines, as shown in the example buffer arrangement 40 shown in FIG. 2, to which reference is now additionally made. In the example illustrated, three wire lines 42, 44, and 46 are shown. The victim wire line 44 is in the middle of two aggressor wire lines 42 and 46 and uses inverting buffers 48 spaced at regular intervals. The aggressor wire lines 42 and 46 on each side of the victim wire line 44 also use inverting buffers 50 spaced at regular intervals, but placed halfway between the inverting buffers 48 in the victim wire line 44 in the staggered pattern shown.

With this arrangement of inverting buffers, the crosstalk to the single victim wire line 44 comes from two sources that have opposite transitions, as shown by waveform 52 and 54. Thus, the crosstalk 52′ from the waveform 52 produces a waveform with a falling edge, while the crosstalk 54′ produces a waveform with a rising edge. Therefore, the charges dumped from the two capacitances 56 and 58 roughly cancel out, reducing the crosstalk effect. However, in many cases, the solution shown in FIG. 2 cannot be used.

An example of one case where the buffer arrangement 40 of FIG. 2 cannot be used is shown in FIG. 3, to which reference is now additionally made. FIG. 3 shows a portion of a buffer arrangement 60 fabricated on a semiconductor chip 62 in which the buffers 64 for both victim wire line 66 and aggressor wire lines 68 are constrained to lie in certain intervals. Here, the forbidden areas are occupied by subchips 70, portions of design of which may be completed separately, such that further additions of logic may not be allowed. Frequently, the subchips 70 occupy the vast majority of the area of the semiconductor chip 62, with narrow gaps 72 between the subchips 70 being the only legal place where the buffers 64 can be located. The subchips 70 are often so large, in fact, that often the buffers 64 must be located in every gap 72 between them. Another type of structure that creates forbidden regions is embedded RAM blocks on the chips.

What is needed, therefore, is a buffer arrangement that reduces crosstalk between victim and aggressor wire lines. Moreover, the buffer arrangement should enable buffers to be located in each gap between subchips when required, while still reducing crosstalk between adjacent wire lines.

### SUMMARY

According to an embodiment of an integrated circuit, at least two substantially parallel wire lines are provided, each wire line including a plurality of alternately arranged inverting and noninverting buffers. The inverting and noninverting buffers are alternately arranged between locations in a first wire line and alternately arranged between adjacent locations in an adjacent wire line.

According to an embodiment of a buffer arrangement on a semiconductor chip, at least one aggressor wire line is located adjacent and substantially parallel to a victim wire line. A plurality of alternately arranged inverting and noninverting buffers are located in the at least one aggressor wire line, and a plurality of alternately arranged noninverting and inverting buffers are located in the victim wire line in locations corresponding to locations of the inverting and noninverting buffers in the at least one aggressor wire line.

A method embodiment is disclosed for arranging a plurality of buffers in a plurality of substantially parallel wire lines on a semiconductor chip. A plurality of inverting buffers are arranged in the wire lines in first areas of a checkerboard pattern, and a plurality of noninverting buffers are arranged in the wire lines in second areas of the checkerboard pattern. The first areas alternate with the second areas along and across respective wire lines.

### BRIEF DESCRIPTION OF THE DRAWINGS

FIG. 1 is an electrical schematic diagram of a portion of aggressor and victim wire lines of the prior art showing an example of a crosstalk mechanism between the wire lines.

FIG. 2 is an electrical schematic diagram of a portion of a number of wire lines of the prior art in which a plurality of offset inverters have been located in respective adjacent wire lines.

FIG. 3 is an electrical schematic diagram of a portion of a semiconductor chip that is occupied by a plurality of subchips and in which buffers are located at each gap between the subchips, according to the prior art.

FIG. 4 is an electrical schematic diagram of three parallel wire lines having a checkerboard buffer arrangement on a semiconductor chip to reduce crosstalk effects in a victim wire line.

FIG. 5 is an electrical schematic diagram of three parallel wire lines having the checkerboard buffer arrangement of FIG. 4, showing the parasitic capacitance coupling between an aggressor wire line and a victim wire line, along with example waveforms therebetween.

FIG. 6 is an electrical schematic diagram of three parallel wire lines having a checkerboard buffer arrangement on a semiconductor chip to reduce crosstalk effects in a victim wire line, in which signals between aggressor and victim wire lines run in opposite directions.

FIG. 7 is an illustration of signals of two very long buffer chains, showing the effect on signals that are simultaneously launched from opposite directions.

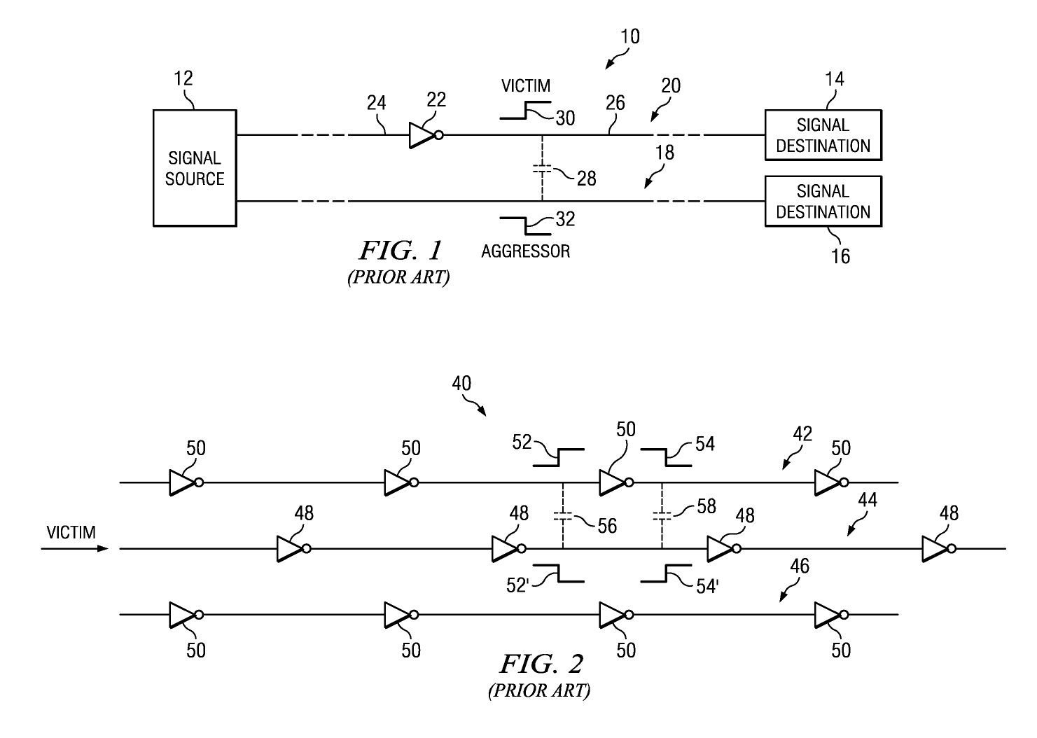

And FIG. 8 is an electrical schematic diagram showing an example of a checkerboard buffer arrangement that can be used in instances where a number of subchips are formed in a semiconductor substrate.

In the various figures of the drawing, like reference numbers are used to denote like or similar parts.

### DETAILED DESCRIPTION

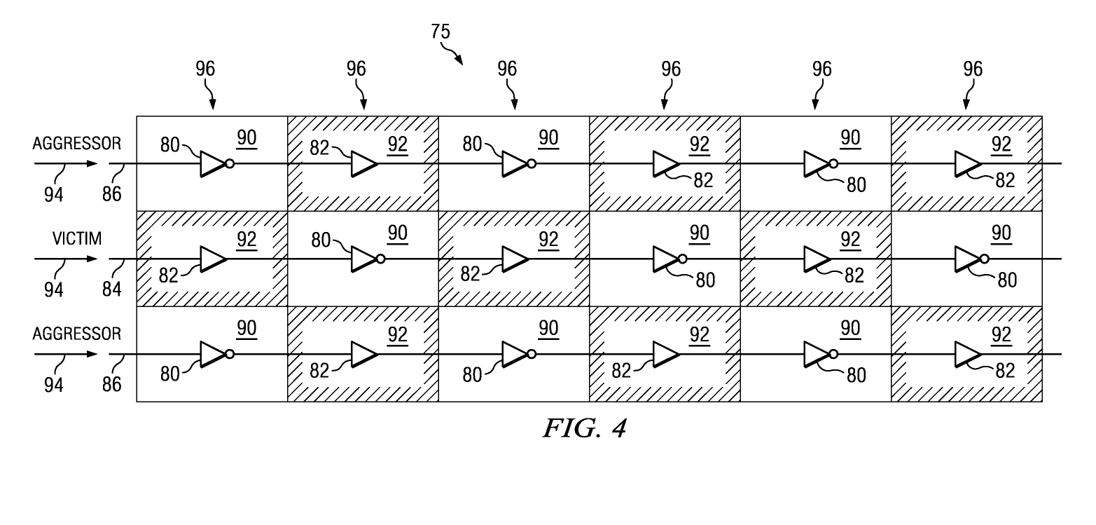

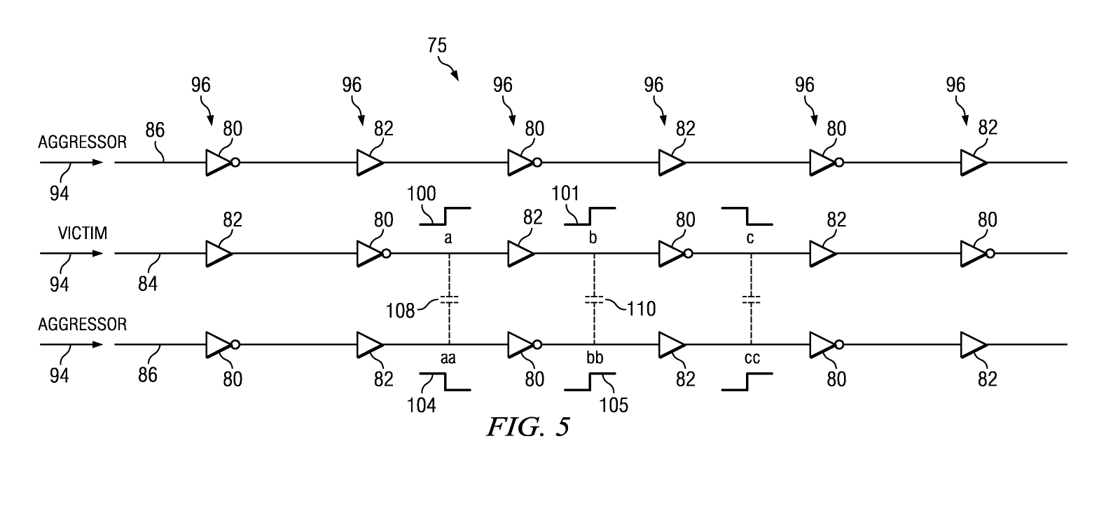

FIG. 4 shows a buffer arrangement 75 to reduce crosstalk in which inverting repeaters and noninverting repeaters (referred to herein as inverting buffers 80 and noninverting buffers 82) are alternately arranged in alternate locations along and across the victim wire line 84 and aggressor wire lines 86. Thus, the inverting buffers 80 and noninverting buffers 82 are arranged in a checkerboard pattern in which areas of a first type 90 are alternated with areas of a second type 92 in rows 94 and columns 96 along and across the wire lines. It should be noted that although three wire lines 84 and 84 are illustrated in this example, the same principles can be extended to any number of wire lines.

In the illustration shown, inverting buffers 80 are arranged in the lines 84 and 86 in areas 90 along the rows 94, and noninverting buffers 82 are arranged in the lines 84 and 86 in the areas 92 along the rows 94. Additionally, along the columns 96, the inverting buffers 80 and noninverting buffers 82 are alternatingly arranged so that, for example, a noninverting buffer 82 is arranged in an area 92 in a column 96 adjacent to an inverting buffer 80 arranged in an area 90 in the column 96. Thus, the buffers 80 and 82 are arranged in an overall pattern in which inverting buffers occupy locations similar to one “color” of a checkerboard, and the noninverting buffers occupy the locations of the other “color” on the checkerboard. The “checkerboard” concept is described only as a simile to aid in the description of the buffer arrangement 75 and would not appear in actual practice.

The effects that are realized through the use of the checkerboard pattern buffer arrangement 75 described in FIG. 4 are illustrated in FIG. 5, to which reference is now additionally made. Two consecutive nodes a and b of the victim wire line 84 with a noninverting buffer 82 between them switch in the same direction, shown by waveforms 100 and 101. However, the two nodes aa and bb of an aggressor wire line 86 switch in opposite directions because they have an inverting buffer 80 between them. This is shown by waveforms 104 and 105. So if aggressor node aa is switching in the opposite direction of victim node a, and therefore slowing down the victim lire line 84 due to the capacitive coupling by parasitic capacitor 108, then one node later, the aggressor node bb is switching in the same direction as victim node bb. The signal at bb is then capacitively coupled to node b by parasitic capacitor 110, thereby speeding up the victim wire line 84.

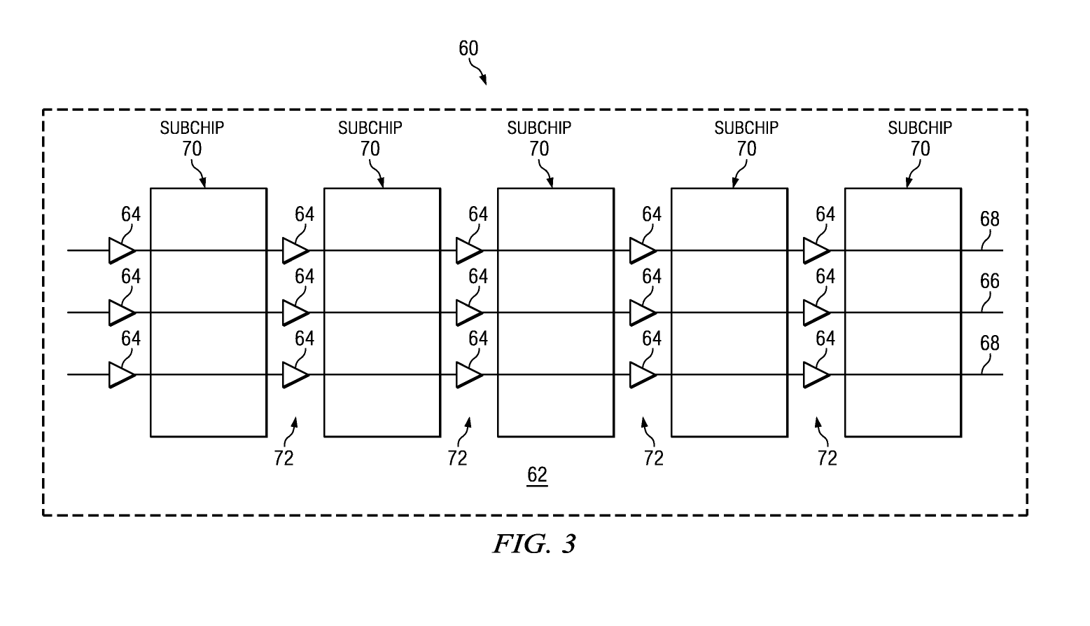

Compared to the case shown in FIG. 3 where all the couplings between the aggressor wire line and victim wire line segments would be slowing the victim wire line down, here it is obvious that only half of the aggressor wire line segments will slow down the victim wire lines, since the signals in the other aggressor wire line segments are moving in the opposite direction. That halves the overall delay effect of the crosstalk. Furthermore, those other half of the aggressor wire line segments will be switching in a direction to cancel out the delay additions from the other aggressor wire line segment interactions, further reducing the crosstalk effects significantly.

Victim nodes b and c switch in opposite directions, while their aggressor nodes bb and cc switch in the same direction. Therefore, if the transition on cc is slowing down victim node c, the transition on bb is speeding up victim node b. In this case the aggressors have the same polarity and the victims are moving in opposite directions, as opposed to the case above considering a, b, aa, and bb, where the victim had the same polarity and it was the aggressors which had the opposite polarities. It does not matter whether the inversion is between the two victim nodes or the two aggressor nodes. As long as exactly one of them inverts and the other does not, the crosstalk effects on the two aggressor-victim pairs are always in the direction of canceling each other out.

In cases where large number of adjacent wire lines need to be run in the same direction, the use of this technique can reduce the overall maximum delay. Noninverting repeaters generally have a larger delay than inverting repeaters, but this effect is reduced by the fact that the first inverter of the noninverting buffer sharpens up the slope of the incoming signal, more effectively driving the second inverter. Using this technique also increases the minimum delay, which helps avoid hold time problems.

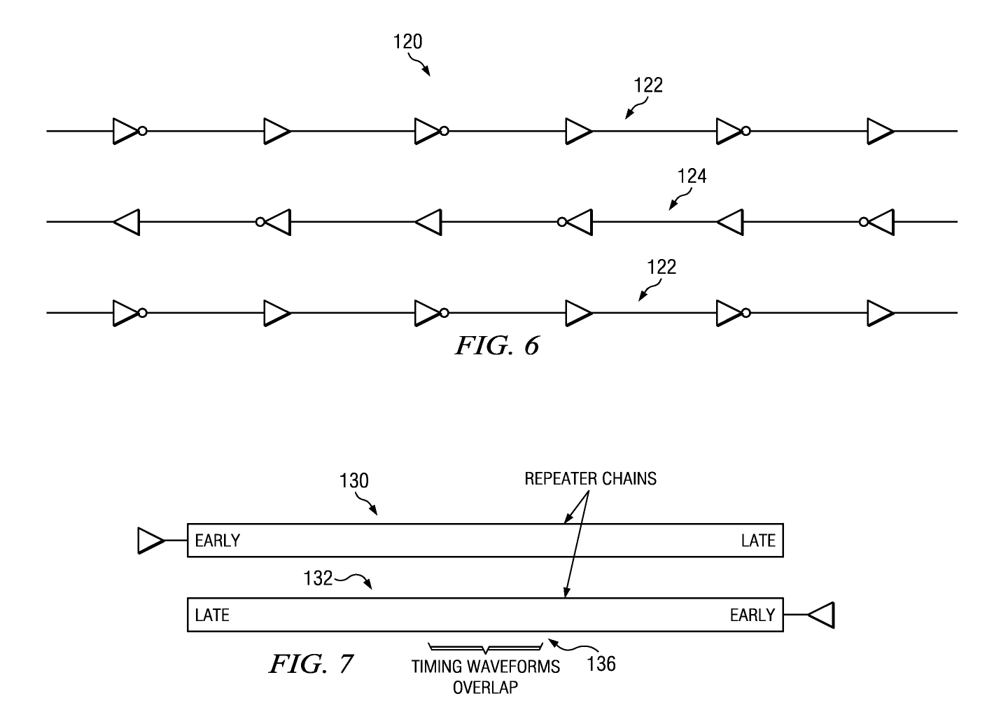

FIG. 6 shows that this same checkerboard technique described above with reference to FIGS. 4 and 5 can be used in an embodiment 120 in which adjacent signals are travelling in opposite directions. Thus, signals in the two aggressor wire lines 122 run in a direction opposite the signals in the victim line 124. In another embodiment, the signals in the two aggressor wire lines 122 may run in opposite directions, wherein the signals in the victim wire line 124 run in a direction opposite to the signals in only one of the aggressor wire lines 122.

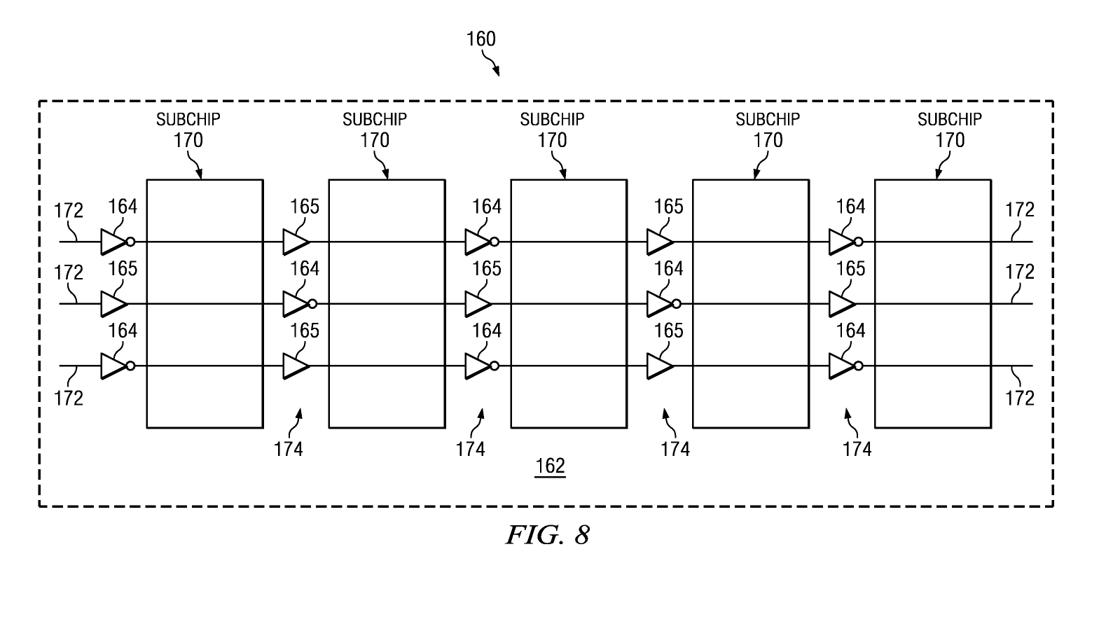

FIG. 7 is an illustration of signals on two very long buffer chains 130 and 132, showing the effect on signals that are launched at the same time, such as at the beginning of a clock cycle, from opposite directions of the buffer chains 130 and 134. Thus, the signals launched on the left end of the buffer chain 130 arrive there early, while the signal launched on the right end of buffer chain 132 arrive late. Therefore, at the left side, since these signals are not switching at the same time at that locale, crosstalk effects do not change the signal delays. Likewise, at the right side, the left to right signal arrives too late to affect the delay of the right to left signal.

However, in the middle region 136 there is a point where the two signal wavefronts cross. The checkerboarded buffer arrangement technique can be used with this oppositely launched signal scenario, and, moreover, may be used only in the middle region 136 where the signal wavefronts actually cross. Thus, on the left and right sides of the wire lines 130 and 132, a standard buffer arrangement where all repeaters have the same polarity may be employed. Note that the middle region 136 where the checkerboard buffer arrangement technique can be used should be large enough to comprehend all possible signal wavefront crossings in the face of delay variations, including CAD tool uncertainty about when and where the wavefronts cross.

The checkerboard buffer arrangement techniques can be used in instances where a number of subchips are formed in a semiconductor substrate 162, as shown in FIG. 8, to which reference is now additionally made. The buffer arrangement 160 illustrated is formed in a semiconductor substrate 162 in which a number of subchips 170 have been instantiated. A number of wire lines 172 run through the subchips 170 from one side of the semiconductor substrate 162 to the other. The inverting buffers 164 and noninverting buffers 165 are arranged in the checkerboard pattern described above, including within the locations 174 between the subchips 170. The analysis of the buffer arrangement 160 in this application is the same as that described above with reference to FIGS. 4 and 5.

Electrical connections, couplings, and connections have been described with respect to various devices or elements. The connections and couplings may be direct or indirect. A connection between a first and second electrical device may be a direct electrical connection or may be an indirect electrical connection. An indirect electrical connection may include interposed elements that may process the signals from the first electrical device to the second electrical device.

Although the invention has been described and illustrated with a certain degree of particularity, it should be understood that the present disclosure has been made by way of example only, and that numerous changes in the combination and arrangement of parts may be resorted to without departing from the spirit and scope of the invention, as hereinafter claimed.

1. An integrated circuit comprising:
at least two substantially parallel rows of wire lines, each wire line including a plurality of inverting and noninverting buffers, said inverting and noninverting buffers being alternately arranged in adjacent locations along a first wire line and being alternately arranged in adjacent locations between said first wire line and an adjacent wire line.

2. The integrated circuit of claim 1 wherein signals in said at least two substantially parallel rows of wire lines run in a same direction.

3. The integrated circuit of claim 1 wherein signals in said at least two substantially parallel rows of wire lines run in an opposite direction.

4. The integrated circuit of claim 3 wherein the alternate arrangement of said inverting and noninverting buffers is located in a region of said at least two substantially parallel rows of wire lines at which wavefronts of said signals that run in opposite directions cross.

5. The integrated circuit of claim 1 wherein said inverting and noninverting buffers are located in lines between subchips in said integrated circuit.

6. The integrated circuit of claim 1 wherein said inverting and noninverting buffers are arranged in a checkerboard pattern.

7. The integrated circuit of claim 6 wherein said inverting buffers are arranged in said wire lines in first areas of said checkerboard pattern, wherein said first areas alternating with second areas of said checkerboard pattern along rows and columns of said wire lines, and wherein said noninverting buffers are arranged in said wire lines in said second areas.

8. A buffer arrangement on a semiconductor chip, wherein at least one aggressor wire line is located adjacent and substantially parallel to a victim wire line, comprising:
a plurality of alternately arranged inverting and noninverting buffers in said at least one aggressor wire line;
a plurality of alternately arranged noninverting and inverting buffers in said victim wire line in locations corresponding to locations of said inverting and noninverting buffers in said at least one aggressor wire line.

9. The buffer arrangement of claim 8 wherein signals in said at least one aggressor wire line and in said victim line run in a same direction.

10. The buffer arrangement of claim 8 wherein signals in said at least one aggressor wire line and in said victim wire line run in a same direction run in an opposite direction.

11. The buffer arrangement of claim 10 wherein said alternately arranged inverting and noninverting buffers are located in a region of said at least one aggressor wire line and said victim wire line at which wavefronts of said signals that run in opposite directions cross.

12. The buffer arrangement of claim 8 wherein said inverting and noninverting buffers are located in lines between subchips in an integrated circuit.

13. The buffer arrangement of claim 8 wherein said inverting and noninverting buffers are arranged in a checkerboard pattern.

14. The buffer arrangement of claim 13 wherein said inverting buffers are arranged in said aggressor and victim wire lines in first areas of said checkerboard pattern, wherein said first areas alternating with second areas of said checkerboard pattern along rows and columns of said aggressor and victim wire lines, and wherein said noninverting buffers are arranged in said aggressor and victim wire lines in said second areas.

15. A method for arranging a plurality of buffers in a plurality of substantially parallel wire lines on a semiconductor chip, comprising:
arranging a plurality of inverting buffers in said wire lines in first areas of a checkerboard pattern, said first areas alternating with second areas of said checkerboard pattern along and across respective rows of said wire lines;
and arranging a plurality of noninverting buffers in said wire lines in said second areas.

16. The method of claim 15 wherein adjacent rows of said substantially parallel wire lines are respective aggressor wire lines and victim wire lines.

17. The method of claim 16 further comprising running signals in said aggressor wire lines run in a same direction as signals in a said victim wire lines.

18. The method of claim 16 further comprising running signals in said aggressor wire lines in an opposite from signals in said victim wire lines.

19. The method of claim 18 further comprising arranging said inverting and noninverting buffers in a region of said aggressor wire lines and said victim wire lines at which wavefronts of said signals that run in opposite directions cross.

20. The method of claim 15 further comprising arranging said inverting and noninverting buffers in lines between subchips in an integrated circuit.
